(19) United States
(12) Patent Application Publication
(10) Pub. No.: US 2008/0284723 A1
(43) Pub. Date: Nov. 20, 2008

(54) Physical User Interface

(75) Inventor: Thomas Andrew Cohen, Western Australia (AU)

Correspondence Address: MICHAEL MOLINS;MOLINS & CO., SUITE 5, LEVEL 6, 139 MACQUARIE ST, SYDNEY NSW, 2000, AU

(73) Assignee: ACEINC PTY LIMITED, West Perth, Western (AU)

(21) Appl. No.: 10/587,098

(22) PCT Filed: Feb. 11, 2005
(86) PCT No.: PCT/AU2005/000173

§ 371 Date: Aug. 4, 2008

(30) Foreign Application Priority Data
Feb. 16, 2004 (AU) 2004900759
Mar. 19, 2004 (AU) 2004901455

(51) Int. Cl. G09G 5/00; H03K 17/94

(52) U.S. Cl. 345/156; 341/20

(57) ABSTRACT

A physical user interface is provided as an adjunct to a graphical user interface to a device having an operating system. The physical interface has a work surface or workspace that is scanned by one or more sensors capable of determining the position of objects. The work surface or workspace is sub-divided into two or more regions. Each region is representative of a user-generated command. In some examples, the one or more sensors adapted to determine the position and orientation of one or more counters. The sensors can distinguish which region a counter is located in and what orientation it is in. The sensors provide an output signal, based on the determination, to the device.

### FIELD OF THE INVENTION

The invention pertains to human—machine interfaces and more particularly to a physical interface between a user and a computer.

### BACKGROUND OF THE INVENTION

A typical graphical interface (GUI) and the typical pointing devices that accompany the GUI, such as a mouse, trackball, touch pad or joystick (‘pointing device’), are frequently not suitable for a young child (and some physically or mentally challenged adults). The amount of information on the display or screen is complex, excessive and the mastery of graphic symbols required to use a typical GUI and pointing device is beyond the grasp of younger children. However, children do have sufficient cognitive skills, spatial orientation and dexterity to use toys such as blocks, toy soldiers and checkers. Equally, a typical GUI and associated pointing device often require fine motor skills and/or good eyesight for frequent and repetitive tasks, such as those customarily required to launch, position, order, re-size and close application windows and to perform certain functions such as scrolling. This can be a source of frustration and strain for users. Additionally, if many application windows are open, a typical GUI will often require a user to close (or minimise) one or more windows in order that the icons used to launch other applications can be seen. This is unproductive. It is not always possible, obvious or easy to use a keyboard as a complete substitute for a pointing device.

### OBJECTS AND SUMMARY OF THE INVENTION

The present invention seeks to provide an interface to a computer that is appropriate to the abilities of younger children, the disabled and/or inexperienced or non-expert PC users.

The present invention also seeks to provide a physical interface to a computer, the interface based on the location of a counter or counters on a surface or within a workspace.

The invention is aimed at average users, certain categories of disabled users and children—it need not be suitable for high-end experienced PC users.

Accordingly there is provided a physical interface having a work surface, or more broadly a workspace, and an associated electronic system consisting of one or more sensors capable of detecting the position of one or more objects in the workspace. The workspace is subdivided (or sub-divisible) into regions separately detectable by the one or more sensors. The interface is connectable as a peripheral to a computer. One or more uniquely identifiable counters are provided. A counter is capable of fitting within a region in or on the workspace (which may or may not be visually and/or physically defined) and each counter is detectable by the sensor(s) scanning the workspace in a way that distinguishes it from other counters. Collectively, the sensors can determine which region a counter is in.

In some embodiments, a signal processor in the device uses the output of the sensors to determine the region of each counter and the identity of each counter and communicates the position and identity data to a control program running on the PC or other electronic product to which the interface is connected. The control program turns that output into a second signal that is capable of being interpreted by a computer as one or more commands.

In some embodiments, a control program provides commands, based on sensor data. Examples of commands are to maximise, minimise or otherwise re-size an application window related to a counter.

In some embodiments the workspace may be three dimensional, with counter locations defined in terms of three axes. The position and type of sensor(s) that scan the workspace may be different depending on the nature of the workspace.

In a further preferred embodiment, the sensor or sensors also detect an orientation of a counter and the signal processor uses the orientation as well as the location and identity data to generate the second signal.

In a further preferred embodiment, the counter contains data storage capacity (memory), and is in communication in a uni-directional or bi-directional manner with the control program. The memory may be pre-loaded ex-factory. If pre-loaded, the data may be deleted once read by the sensors and the control program, or the data may be permanent and non-erasable. Further, data may be downloaded from the PC to the counter. The downloaded data may be permanent, transient (present until over-written or erased), or ephemeral (deleted the next time the counter data is read by the PC). A counter may be pre-set at the factory to launch a given application, for example when packaged with a game. A combination of permanent, transient, and ephemeral data may co-exist in the memory of a single counter.

Counters may be transferable from an interface connected to a PC or other electronic product to a similar interface connected to another PC or electronic product. For example, the association recorded between a counter and an application ex-factory or by the interface on a first PC could, if the same application is installed on a second PC, allow the user to continue to use the application without a new association having to be made between the counter and the application. Furthermore, the data recorded at one PC could be used on another PC or with another application on the same or other PC.

The types of data stored on the counters include, but are not limited to, a) security keys or passwords; b) settings, properties, and data associated with a specific application; c) player profiles, login data and personal avatars for games, instant messaging, etc.; and d) applets or other applications.

### BRIEF DESCRIPTION OF THE DRAWING FIGURES

FIG. 1 is a perspective view of an example of a physical interface according to the teachings of the present invention.

FIGS. 2 (a)-(c) are top plan views of embodiments of counters.

FIG. 2 (d) is a side elevation of a counter.

FIG. 3 depicts perspective views of counters.

FIG. 4 is a triangular surface arrangement of a physical user interface.

FIG. 5 is another triangular surface arrangement of a physical user interface workspace.

FIG. 6 is a sub-surface antenna arrangement of an RFID type physical user interface.

FIG. 7 is a cross section view of a double-sided RFID counter.

FIG. 8 is graphic representation of a tab or menu bar.

### BEST MODE AND OTHER EMBODIMENTS OF THE INVENTION

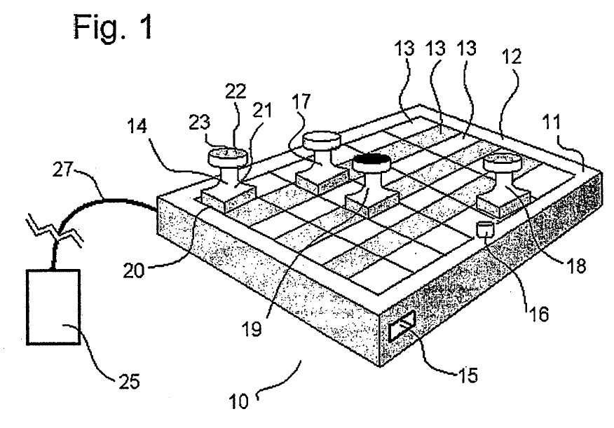

As shown in FIG. 1, one embodiment of the disclosed technology 10 comprises a case 11 having a flat, smooth, impermeable top surface 12. This surface is deemed a workspace. The term “workspace” is intended to cover any surface or combination of surfaces upon which a “counter” can be located. A workspace may also be a region of space bounded by appropriate sensors or alternately, 2 or more layers of surfaces (as mentioned above and discussed below) operating cooperatively. In the context of this invention, a counter is a physical token that can be detected, located and optionally read and/or written to by one or more sensors that scan, read or interrogate the workspace.

The workspace's surface could equally be shaped or textured to define the different regions and/or positions within regions. The interaction between a counter and the workspace could be magnetic or otherwise non-slip or adhesive to prevent counters sliding accidentally. The top surface is subdivided into regions 13. In this example, regions 13 are arranged as a matrix of rows and columns. There is provided a number of counters 14 which can be placed on the surface. A counter 14 fits within a region 13.

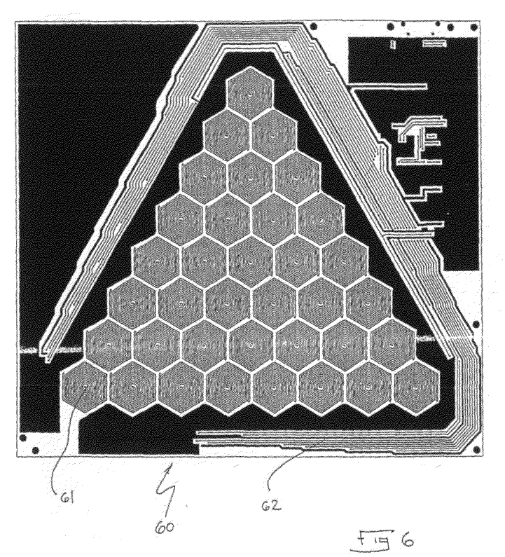

An electronic substrate or array of sensors below the upper or work surface 12 (not shown, but suggested by FIG. 6) consists of a mechanism or array capable of detecting the row and column position or more generally, the location of each of the counters 14. Each counter is uniquely identifiable by the array of sensors, in that each counter can be distinguished from every other counter in the set of counters. For this purpose one can use radio frequency (RFID), magnetic, optical, Hall effect, capacitance or other technologies which provide the required interaction between counter 14 and sensor, for example, a unique RFID chip or combination of magnets embedded in each counter. The sensor or array of sensors repeatedly and frequently scan(s) the surface 12 and optionally reports either the changes (eg a re-location of a counter, removal of a counter or placement of a new counter on the work surface) or the positions of all counters. If RFID technology is used, with each counter 14 provided with its own RFID chip or chips, the substrate contains one or more sensing antennae of the type shown in FIG. 6.

The interface 10 is connected to a computer 25, via a data path 27. The data path may be a USB cable, wireless communication connection, or other uni-directional or bi-directional technology. The data path is connected directly or indirectly to a control program that communicates with the operating system and/or application programs running on the computer 25.

The interface may be run in series with a USB (or similar) mouse and may have a spare USB (or similar) port 15 for this purpose. It may also be run as a stand-alone interface with an integrated touchpad/trackpoint or other pointing device 16. Its presence will have no effect on the operation of the mouse or other pointing device.

Control software on the PC will allow the user to assign (and re-assign) to each counter an association with an application on the PC. For example, counter 17 might be a browser, counter 18 an email client, counter 19 is a word processing application. The control program communicates with operating system and/or application programs, transfers any data from the relevant counters on the interface surface and may write to them as well (either directly from its own interface, or as a conduit on behalf of an associated application program or other program or operating system on the PC). The control program also communicates with the operating system to start and stop application programs, to layer open windows and to re-size (including to minimise) windows.

A counter 17 may have data storage capacity or memory in the form of flash memory or other read/write (or read-only technology). The sub-surface sensors may interface with magnetic, infrared, RFID, or other bi-directional signal technology, so that the data in the counter may be read, written, updated, or erased. Thus when a counter 17 with memory is placed on the surface, the region 13 where the counter is located is identified and any data in the counter's memory is transferred to the connected computer 25 via the data path 27. Data on any counter may be read, written, updated, or deleted by the control program independently.

Data stored in a counter's memory may be permanent, transient, or ephemeral, or any combination of these. Permanent data may be recorded during or after manufacture, or on first use, and remains without change. Transient data may be read, written, updated, or deleted, for example, by an associated application program. Ephemeral data is deleted once read. A counter used in any embodiment of the invention may have a combination of these. For example, the identity of the associated application may be permanent data so that the counter is always used with and identifies the same program. User preferences may be transient data so that they remain constant until changed by the user. Temporary application state or status data may be ephemeral.

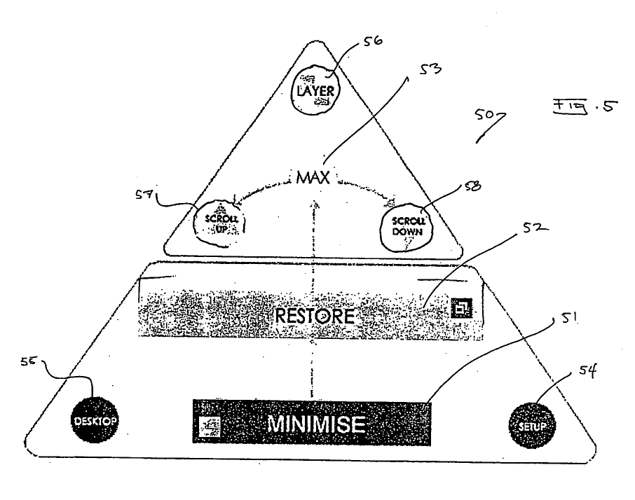

When a new counter (previously unused) is placed on a region 13 (or 51-58 in FIG. 5), the control software setup interface may launch automatically and prompt the user to associate the new counter with an application.

In the alternative, when a new counter (previously unused but with stored data) is placed on a region 13 (or 51-58 in FIG. 5), the control software may launch an associated application automatically (if not already running) or may prompt the user to associate the counter with a default or selected application based on the counter's stored data in the counter's memory. Any related data on the counter could then be read and transferred to or used with the associated or selected application.

Once a counter is associated with an application, the consequence of a new instance of use on the surface 12 is like a mouse click on a desktop icon. However, once an application is launched, previously recorded application data on the counter may be transferred to the application without user interaction.

In one implementation, a specific region on the surface may be designated as a ‘set-up’ region—and when any marker is placed there, whether or not previously associated with an application, the control software setup interface will launch and will allow a first or new assignment as the case may be (see below).

When a counter is removed from the surface (either lifted off completely or slid to a non-active zone outside the matrix of regions) and has not been replaced within a designated time, the associated application may close automatically (or at least commence a close routine). While the counter is located on the surface, the application may update data on the counter according to the design of the application and the interactions with the user. Transient data may be updated and ephemeral data erased once read. As the counter may be moved or removed by the user at any time, the application is designed so that transient data is updated in a timely manner.

In an alternative implementation buffer zones may be provided around active regions on the surface whereby if a counter is accidentally knocked and moves into a non-active zone (but within the detection range of the sensor array), the software will not alter the window state of the associated application.

Moving a counter on a surface of the type exemplified in FIG. 1 has the following effects: The horizontal axis (or row position) represents the side-to-side position of the application window on the PC's GUI desktop. The vertical axis (or column position) represents a) the size of the application window as a percentage of its maximum size; and b) the relative positions (layering) of all open windows. The application associated with the counter highest on the vertical axis will be on top of all other open applications (except and optionally those programmed to be ‘always on top’).

As shown in FIG. 1, a counter 14 may have a base 20 that provides a stable foundation as well as a physical platform for identification hardware such as magnets, bar codes, etc. In this example, a stalk 21 separates a head 22 from the base 20. The head makes the counter 14 easy to handle and provides a top surface that can be used to identify the counter.

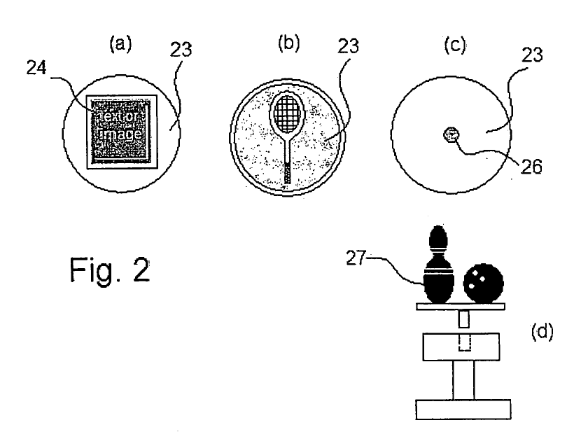

As shown in FIG. 2, the top surface 23 of a counter may support a miniature display 24 capable of displaying text or images that identify the counter and its associated application. The surface 23 (or any other surface of the counter) may alternatively be used to put an identifying label 25 on. The top surface 23 may also have a fixture 26 for receiving user selected three dimensional indicia; 27 which cooperate with the surface 23 or fixture 26 and which identify the counter and its associated application.

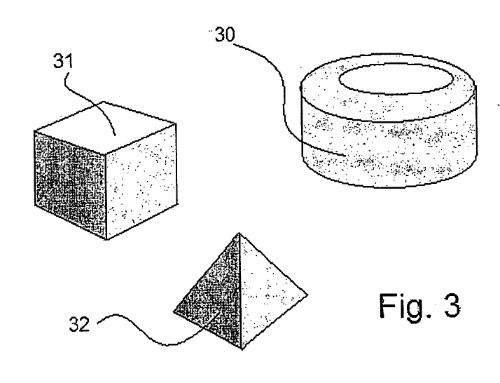

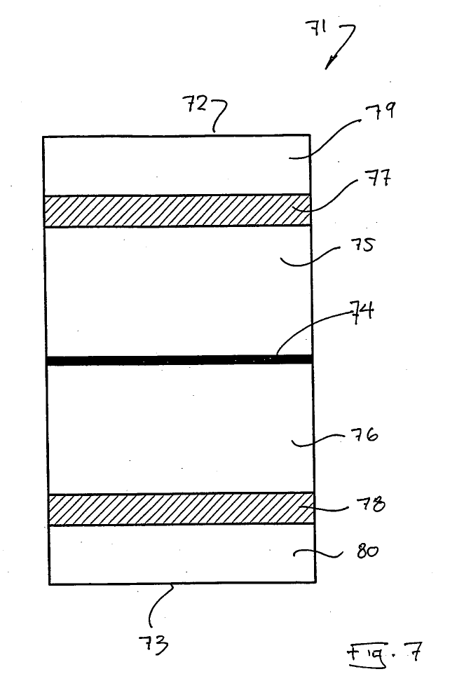

As shown in FIG. 3, a counter may be a cylinder or disk 30, cube 31, tetrahedron 32 or other three-dimensional solid. Solids of this type have a discrete number of stable rest positions associated with their faces. E.g. the cube has six, the tetrahedron has 4 and the cylinder has two. In this way, a counter may have multiple orientations. An orientation is a stable position in which a counter can be read by a sensor in a way that provides data unique to that orientation. To accomplish this, an orientation may be unique to that face of a polyhedron or other solid shape that is face down on the worksurface. Thus, an RFID chip or other readable feature needs to be associated with each face that is intended to signify an orientation. An orientation is said to be stable if the counter is mechanically stable on or in the workspace and a unique output is rendered by the sensor. Where RFID chips are used as the readable feature, each RFID transmitter in a counter can be isolated from the others in ways suggested by FIG. 7 and its related disclosure. RFID chips may also be isolated from one another by tailoring the transmission energy of the RFID chip or the read sensitivity of the sensor.

In another 50, such as that shown in FIG. 5, moving a marker will have the effect designated in each region (minimise 51, restore 52 and maximise 53). It will be noted that this example or implementation includes the following additional user features: a) a set-up region 54; b) a ‘minimise all’ region 55 (labelled ‘desktop’); c) a ‘send to back’ region 56 (labelled ‘layer’) which sends a full screen window to the back, allowing smaller windows to be seen; and d) scroll up/down regions 57, 58. A large number of counters may be placed in the ‘restore’ and ‘minimise’ regions. The only practical limitation (other than any limitation imposed by the scanning technology) is physical space—which is simply a function of design layout and counter size. The last moved counter in ‘restore’ (whether moved to ‘restore’ from elsewhere or moved within the region) will be on top of all other restored windows and will have keyboard focus. A counter moved to ‘max’ 53 will take keyboard focus and optionally will retain it even if another counter is later moved to ‘restore’ (i.e. the restored window would be layered underneath the maximised window). If the maximised window is sent to the back (‘layer’), while it is there, keyboard focus will be given to the top ‘restored’ window. When a counter is placed on ‘set-up’ 54 an application window will show the currently open applications with the sole exception of any open applications already associated with other counters (whether or not those other counters are on the surface of the interface). The counter on ‘set-up’ (whether already associated with another application or not) can then be associated with any one of the displayed applications (by using the keyboard arrows to highlight the selected application, and clicking ‘enter’). If the counter had already been associated with another application, the previous association will be overwritten by the new association. Placing a counter on ‘desktop’ 55 will minimise all open windows. Removing the counter from ‘desktop’ 55 will return all windows to the sizes and locations indicated by the counters on the surface of the interface. ‘Restore’ 52 can optionally generate a random size and location for a window (as per the WINDOWS restore command) or can tile windows in a designated pattern. The scroll buttons 57, 58 cause the content displayed in a full screen window to scroll up or down as indicated until the counter is returned to the ‘max spot. Optionally a user can be given the ability to pre-set a scrolling speed. When a counter is removed from the scanned surface of the interface the associated application immediately minimises and the close routine is then initiated after a short optionally adjustable delay—this allows time for the user to change his/her mind. Without departing from the principle of allowing a counter's position and orientation to open an application, to designate a window's location and/or relative size/order and to control certain features as set out above, it is possible to assign to a region control of other features of the Windows operating system and/or specific associated application.

If the mouse (or other pointing device) has been used to re-arrange the desktop, any movement of any counter will re-set the desktop to the layout described by the positions of the counters. When a counter is placed on the ‘restore’ region, or moved within the ‘restore’ region, optionally when the associated application is restored and given keyboard focus, the cursor or pointing device on screen indicator can be temporarily highlighted or automatically repositioned to a standard, or pre-selected or default location (such as the top left hand corner of the screen). This makes it easier for the user to navigate within the application window using the keyboard controls or other pointing device.

In one embodiment a counter will only have one identity, irrespective of which face is in contact with the work surface (or because the counters have a defined ‘top’ and ‘bottom’ and cannot be rotated).

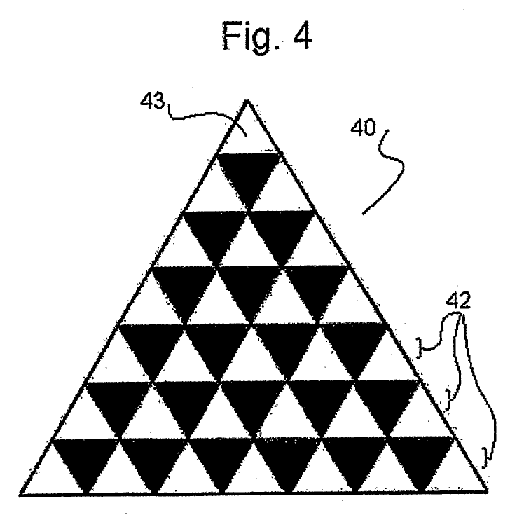

As shown in FIGS. 4 and 5, a surface 11 need not be square or rectangular. The embodiment of FIG. 4 is a triangular surface 40 subdivided or tessellated into triangular regions 41 is well suited to the invention because while still having rows 42 for indication of horizontal position and relative GUI window size, there is only one location (e.g. the “apex” 43) for a counter's associated programme in the GUI to be at full screen and on top of all other open applications.

The top triangle or apex (43, 56 see FIG. 5) can only be occupied by a single counter—and the first counter there takes priority. It represents a full screen window—and only a full screen window can be scrolled. The full screen window will cover all other windows unless the counter is moved to ‘layer’, in which case it is sent to the back, revealing any windows underneath. Returning the counter to ‘max’ from ‘layer’ returns the maximised window to the top and restores to it the keyboard focus. If a second counter is moved on to any region in the top triangle while the first counter is still there, nothing will happen and the window associated with that second counter will stay in the state it was in prior to the second counter being moved (or will not open if the counter is being placed onto the surface for the first time). These scroll, max and layer functions occupy the upper bounded triangular sector of the workspace 50.

Irrespective of the shape of the work surface, the bottom row can indicate launched applications running minimised. So too, the work surface can be embedded in some larger surface (and would be designated by a graphic design), allowing the creation of ‘inactive areas’ (places where there are no sensors) outside the work surface. Counters could then be slid to these areas to terminate running applications and for storage. When a counter is moved to ‘minimise’ from some other location on the board, or is placed there for the first time from outside an active region, an on-screen flag may be generated to confirm that the application is running minimised (rather than been closed).

The counters may be in a portable form. One example is a counter in the form of a key ring. Another example is a player token or counter is included in a game, or provided or purchased separately from the game. In these examples, the portable counter could represent an avatar in an associated application game that is updated during play. In another example, when a counter is removed, it contains status information so that the game can be continued at a later time.

In another example, a security key is stored on a counter. An associated application is protected by a password, so that the application will not run or will not continue until the user places the counter on the surface and the password entered by the user agrees with or combines with the security key so as to indicate that the user is verified.

As shown in FIG. 6, a sub-surface antenna array assembly 60 comprises a triangular (or other) array of spiral RFID antennae 61 and associated circuit tracks 62 and components. The triangular array of closely packed or tessellated antennae is positioned in registry and below the graphic surface or work surface 50 shown in FIG. 5. All regions within the large triangular area (bordered by the peripheral linear circuit tracks 62) are scanned by the antenna array (nominally once every 5 milliseconds)—so that if a counter is moved (accidentally) from a designated active region (eg ‘restore’) but is still inside the border and not in another active region, the “close application” routine that is initiated when a marker is completely removed will not be run. This prevents accidental closure of applications.

Each spiral element in the antenna array contains a tuned loop antenna circuit and a switch. The antenna switches are low capacitance, types connected to an RFID transceiver. One suitable transceiver is the type S6700 Multi Protocol Transceiver provided by Texas Instruments. It operates on a frequency of 13.56 MHz. This is a low power consumption device and supports multiple RF communication protocols. The maximum radiator power is about 200 mW at 5V. The communication interface is serial. The transceiver chip supports an ISO 15693-2 protocol. The ISO 15693-3 protocol required to interrogate the RFID markers is implemented in the firmware. The interface thus draws its power from the USB bus.

As suggested by FIG. 6, the antenna array is scanned from top down and from left to right. Every time a new antenna is selected, the interface will wait for about 1 ms for the tag to energise and then it will send the Read Signal Block 0 command. For more details, see standard document ISO 15693-3. If there is no tag present in the vicinity of the selected antenna, the firmware will wait for 2 ms and then select the next antenna and repeat the interrogation process. If a tag is present, it will respond by sending 1 block (4 bytes) of data. The first received byte contains the tag ID. The valid range is from 1 to 255; therefore the maximum number of markers supported is 127. If necessary, the tag ID storage can be extended over a number of bytes and the number of supported markers will increase accordingly.

The firmware stores all current tag IDs into a 36 byte arrangement that is sent to the host computer via the USB bus upon request. The tag interrogation protocol includes the CRC error correction algorithm specified by standard ISO/IEC 13239 to protect against noise, interference and corrupt messages. The firmware in the reader and the tag calculates the CRC16 for every message sent and received. All messages with incorrect CRC16 are ignored:

The USB communication mode is high speed (12 Mbps). Data is sent to the host computer via 1 USB pipe from Endpoint 1 (EP1). To ensure a guaranteed and timely data delivery EP1 mode is “interrupt”. The selected polling interval is preferably 2 ms. The RFID scanning routine is interleaved with the USB routines. The content of the tag array is sent to the computer after each and every antenna interrogation is completed. This will ensure a minimum delay between the user placing or moving a counter on the interface and the corresponding ID being sent to the host computer.

To allow for future features expansion, the data packet starts with a header. The first byte in the header contains flags. If the most significant bit is set (first byte=0×80), the following succession of data bytes carries tag ID information. The remaining bits are reserved for future editions and are currently 0. The second byte contains the length of the data packet, which is in the present example 36.

The total length of the data packet is 2 bytes (header) plus 36 bytes (data), providing a total of 38 bytes.

In another embodiment, and as shown in FIG. 7, the unique identification of a counter 71 will vary depending upon which of its faces or surfaces 72, 73 is in contact with the work surface. The RFID chip or other means of identification presented by a counter to a scanner is referred to as the counter's orientation. Thus, a counter may have 2 or more orientations in the same region. Accordingly, in this implementation, the identity of the counter will include two notional fields—a primary ordinal which will be associated with a single application on the user's PC (as above) and a second ordinal (numbered from 1 to n, where n is the number of significant faces on the solid shape). Other means of identifying the individual faces of a counter are possible. When the counter is flipped or re-oriented from one face to another, there will be a corresponding action within the associated application. In one example, if the application is a word processor, flipping a cylinder 30 from one flat face to the other causes the associated programme to step or cycle through all open word processing documents. That is, for a first state of a display, once a counter is inverted or flipped, re-inversion (re-orientation) does not result in the restoration to the first state. In this case, flipping the counter (changing the orientation) has the same effect as pressing Control F6, in WINDOWS, on the keyboard. Other actions are possible—for example, flipping a marker on the ‘set-up’ region may launch the computer's ‘shut-down’ routine.

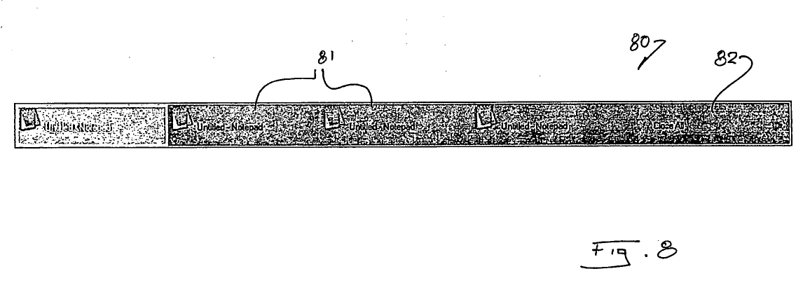

In another alternative relating to ‘counter flipping’ systems, when there are multiple instance of a single application (or multiple open files/documents within an application), flipping the counter associated with that application (re-orientation) may reveal a ‘tab bar’ or menu on the user's graphical display. This type of graphic is depicted in FIG. 8. The tab or menu bar 80 may display in a text and/or graphic form the currently open instances 81 or files for an application associated with a flipped or re-oriented counter and will enable the user to use the keyboard's ‘Tab’ key or arrow keys to move or scroll from one file to the next. Once the selected file or instance is visually highlighted, clicking the ‘enter’ key of a keyboard (or the like) will simultaneously hide the “tab bar” and will display the selected file or instance in the window controlled by the counter. Optionally the tab bar will also display a ‘close all’ button 82 which would allow the user to close all instances or files at one time, either by selecting the Option and simply clicking ‘enter’, or by selecting the option, clicking enter and then lifting the counter from the surface of the interface. The tab bar may ‘float’ or may be attached to the currently controlled instance of the associated application.

In the example of FIG. 7, the counter is for example a disk having the following layered structure. A ferrous magnetic shield layer 74 is sandwiched between two layers of non-ferrous filling material 75, 76. These three layers are sandwiched between two RFID tag layers 77, 78. The outer upper and lower layers are non-ferrous filling material 79, 80. Thus the counters in this example are double sided with back-to-back RFID chips separated by magnetic shield or radio-insulating layer. Each pair of RFID chips may represent sequential odd and even numbers, with, for example, the odd number always being the lower of the two—so, 1 and 2, 3 and 4, etc. When a counter is first placed on the board it is irrelevant which way up it is—either RFID number will be recognised and its associated data number in the pair can be easily calculated.

In preferred embodiments, each tag has 64 blocks of non-volatile user memory area. One block is reserved for the ID, leaving the remaining 63 blocks (252 bytes) available for other user data. Each counter preferably contains two tags, so the total storage capacity is 2×252 bytes. The memory size can be increased, if required.

When saving data into a counter, the host computer should save in a file or registry key, the tag ID. When a future attempt of accessing data is made, if the counter is positioned incorrectly, with the corresponding tag facing up, the software should prompt the user to re-orient the counter so that the appropriate face is exposed to the sensor(s) before reading the data from the tag. Data that can be saved includes programme settings (usually command line parameters) and user passwords. For security reasons, passwords should be encrypted. If the application data is lengthy, it should be saved on the host PC and only an index should be saved into the marker.

As previously mentioned, each counter in a first preferred embodiment contains 2 encapsulated transponders separated by a metallic shield. Only the side exposed to the sensor(s) scanning the work surface will successfully be interrogated. The 13.56 MHz encapsulated transponder from Texas Instruments is compliant with the ISO/IEC 15693 standard, a global open standard that allows interoperability of products from multiple manufacturers. With a user memory of 2 k bits, organised in 64 blocks, this rugged style transponder is especially designed and tested for applications that can withstand harsh environments. Each transponder has an ID pre-programmed before being enclosed within the counter. The transponder pair in a given counter has the individual IDs in sequence, one being odd and the other one even. Markers may be provided with a unique colour to allow users to distinguish one marker from another. Other schemes may be used to distinguish counters from one another.

While the invention has been described with reference to particular details, these should be understood as having been provided as examples and not as limitations to the scope or spirit of the invention.

What is claimed is:

1-22. (canceled)

22. A physical user interface for a microprocessor device that runs an operating system, comprising:
an array of sensors located below a workspace;
the workspace divided into regions that are discernible to a user, each region signifying a command to or an action performed by the operating system;
one or more tokens that are uniquely identifiable by the sensors, each sensor producing a recognition signal;
a signal processor for determining, from the recognition signal, the identity of a token and the region that token is in and producing an associated first output;
a control program for turning the first output into a second output that is capable of being interpreted by the operating system as a command.

23. The physical user interface of claim 22, wherein:
the sensors are RFID antennae and the token is a RFID token.

24. The physical user interface of claim 22, wherein:
the command is one that relates to the organisation of a desktop of a graphical user interface.

25. The physical user interface of claim 22, wherein:
the token identifies, to the operating system, a specific executable program and the command relates to the specific program.

26. The physical user interface of claim 22, wherein:
the token has a memory that can be written to by the interface and that carries data that may be read by the interface, the data that is read being provided by the control program to the operating system.

27. The physical user interface of claim 22, wherein:
the command is one that relates to the size or position of a window in a graphical user interface and is one selected from the group comprising: open, close, restore, scroll, minimise or maximise.

28. A microprocessor device that runs an operating system having:
a physical user interface comprising an array of sensors located below a workspace;
the workspace divided into regions that are discernible to a user, each region signifying a command to, or an action performed by the operating system;
one or more tokens that are uniquely identifiable by the sensors, each sensor producing a recognition signal;
a signal processor for determining, from the recognition signal, the identity of a token and the region that token is in and producing an associated first output;
a control program that for turning the first output into a second output that is capable of being interpreted by the operating system.

29. The microprocessor device of claim 28, wherein:
the sensors are RFID antennae and the token is a RFID token.

30. The microprocessor device of claim 28, wherein:
the command is one that relates to the organisation of a desktop of a graphical user interface.

31. The microprocessor device of claim 28, wherein:
the token identifies, to the operating system, a specific executable program and the command relates to the specific program.

32. The microprocessor device of claim 28, wherein:
the token has a memory that can be written to by the interface and that carries data that may be read by the interface, the data that is read being provided by the control program to the operating system.

33. The microprocessor device of claim 28, wherein:
the command is one that relates to the size or position of a window in a graphical user interface and is one selected from the group comprising: open, close, restore, scroll, minimise or maximise.

34. A method for organising and displaying graphic information on a desktop of a GUI interface to a device having an operating system, comprising the steps of:
placing or relocating a token on a physical workspace below which is located an array of sensors, the token representing a specific program that can be run by the operating system;
the workspace divided into regions that are visible to a user, each region signifying a command to, or an action performed by, the operating system;
the sensors producing a recognition signal when a token is placed into or removed from a region;
the operating system receiving and implementing commands that relate to the organisation of the desktop, from a control program, based on the recognition signal.

35. The method of claim 34, wherein:
the sensors are RFID antennae and the token is a RFID token.

36. The method of claim 34, wherein:
the token identifies, to the operating system, a specific executable program and the command relates to the specific program.

37. The method of claim 34, wherein:
the token has a memory that can be written to by the interface and that carries data that may be read by the interface, the data that is read being provided by the control program to the operating system.

38. The method of claim 34, wherein:
the command is one that relates to the size or position of a window in a graphical user interface and is one selected from the group comprising: open, close, restore, scroll, minimise or maximise.

39. The physical user interface of claim 26, wherein:
the data provided to the operating system is then usable as input data to a specific executable program.

40. The microprocessor device of claim 32, wherein:
the data provided to the operating system is then usable as input data to a specific executable program.

41. The method of claim 37, wherein:
the data provided to the operating system is then usable as input data to a specific executable program.
